(19) United States
(12) Patent Application Publication
(10) Pub. No.: US 2017/0212165 A1
(43) Pub. Date: Jul. 27, 2017

(54) RESISTANCE MEASUREMENT-DEPENDENT INTEGRATED CIRCUIT CHIP RELIABILITY ESTIMATION

(71) Applicant: GLOBALFOUNDRIES INC., Grand Cayman (KY)

(72) Inventors: Jeanne P. Bickford, Essex Junction, VT (US); Nazmul Habib, Colchester, VT (US); Baozhen Li, South Burlington, VT (US); Tad J. Wilder, South Hero, VT (US)

(73) Assignee: GLOBALFOUNDRIES INC., Grand Cayman (KY)

(21) Appl. No.: 15/005,819

(22) Filed: Jan. 25, 2016

(51) Int. Cl. G01R 31/28; H01L 21/66

(52) U.S. Cl. CPC G01R 31/2858; H01L 22/20

(57) ABSTRACT

Disclosed herein are methods for making integrated circuit (IC) chip reliability estimations based on resistance measurements and for using such estimations to disposition manufactured chips. In the methods, a resistance-to-electromigration fail rate correlation can be empirically determined for an integrated circuit chip design. Additionally, for each chip manufactured according to the design, at least one resistance monitor can be used to acquire a resistance value for that manufactured chip. Then, given the resistance value and the resistance-to-electromigration fail rate correlation, the expected reliability of the manufactured chip can be estimated and the manufactured chip can be dispositioned in a variety of different ways.

### FIELD OF THE INVENTION

The present invention relates to the manufacture of products that incorporate integrated circuit chips and, more particularly, to methods for making integrated circuit (IC) chip reliability estimations and for using such estimations in deciding whether or not to allow particular manufactured IC chips to be incorporated into specific product(s).

### BACKGROUND

Various failure mechanisms can cause the components (e.g., devices, interconnects, etc.) of an integrated circuit (IC) chip to degrade or fail. These failure mechanisms include, but are not limited to, time-dependent dielectric breakdown (TDDB) of the gate dielectric layer or between metal lines, hot carrier injection (HCI), negative bias temperature instability (NBTI), positive bias temperature instability (PBTI), soft error rate (SER), retention disturbance, stress migration (SM) (also referred to as stress-induced voiding (SIV)) and electromigration (EM). Over time these failure mechanisms can impact performance (e.g., operating speed) and/or lead to IC chip failure. In order to ensure that manufactured IC chips will meet reliability specifications despite these failure mechanisms, reliability qualification is performed prior to shipping out manufactured IC chips and/or incorporating them into products. However, more efficient techniques are needed for monitoring the manufacturing line and for determining the reliability of particular parts in the product distribution, particularly after the technology has been qualified.

### SUMMARY

In view of the foregoing disclosed herein are methods for making integrated circuit (IC) chip reliability estimations based on resistance values, which can be correlated to the electromigration (EM) fail rate and, thereby the overall fail rate, and for using such estimations to disposition manufactured IC chips (e.g., to decide whether or not to allow particular manufactured IC chips to be incorporated into specific product(s)). In the methods, a resistance-to-EM fail rate correlation can be empirically determined for an integrated circuit chip design. Additionally, for each IC chip manufactured according to the design, at least one resistance monitor can be used to acquire a resistance value for that manufactured IC chip. Then, given the resistance value and the resistance-to-EM fail rate correlation, the manufactured IC chip can be dispositioned in different ways depending upon whether one specific product or multiple different product can incorporate IC chip(s) manufactured according to the IC chip design.

More particularly, one method disclosed herein can apply to a situation where IC chips manufactured according to an integrated circuit (IC) chip design are to be incorporated into a specific product. In this method, a resistance-to-electromigration (EM) fail rate correlation for the design can be empirically determined. Additionally, a product-level reliability requirement for the specific product can be determined along with a chip-level reliability requirement necessary to achieve the product-level reliability requirement. Given the resistance-to-EM fail rate correlation, a maximum resistance threshold for ensuring that the chip-level reliability requirement is met can be defined. Subsequently, IC chips can be manufactured according to the design and, for each manufactured IC chip, at least one resistance monitor can be used to acquire a resistance value for the manufactured IC chip. The manufactured IC chip can then be disposition based on that resistance value. Specifically, the resistance value can be compared to the maximum resistance threshold and the manufactured IC chip can be allowed to be incorporated into the specific product (e.g., shipped out for product assembly) only when the resistance value of the manufactured IC chip is below the threshold. Otherwise, the manufactured IC chip can be scrapped or recycled.

Another method disclosed herein can apply to situations where IC chips manufactured according to the same integrated circuit (IC) chip design could be incorporated into various different products having various different product-level reliability requirements and, thereby different chip-level reliability requirements. In this case, multiple resistance process windows corresponding to different resistance ranges within the full resistance range for an integrated circuit (IC) chip design can be defined. Additionally, a resistance-to-electromigration (EM) fail rate correlation for the design can be empirically determined. Based on this resistance-to-EM fail rate correlation, expected reliability ranges can be associated with the different resistance process windows, respectively. Then, for the different products designed to incorporate at least one of the manufactured IC chips, product-level reliability requirements and chip-level reliability requirements necessary to achieve the product-level reliability requirements, respectively, can be determined and, based on these chip-level reliability requirements, each of the products can be associated with at least one of the resistance process windows. Subsequently, IC chips can be manufactured according to the IC chip design and, for each manufactured IC chip, at least one resistance monitor can be used to acquire a resistance value for the manufactured IC chip. The manufactured IC chip can then be disposition based on that resistance value. Specifically, based on the resistance value, the manufactured IC chip can be associated with a specific resistance process window such that it is selectable for incorporation into a specific product when that specific product has been associated with the same specific resistance process window.

### BRIEF DESCRIPTION OF THE SEVERAL VIEWS OF THE DRAWINGS

The present invention will be better understood from the following detailed description with reference to the drawings, which are not necessarily drawn to scale and in which:

FIG. 1 is a flow diagram illustrating a method for making integrated circuit (IC) chip reliability estimations;

FIG. 2 is a graph illustrating the correlation between the electromigration (EM) fail rate and the overall fail rate of IC chips manufactured according to an IC chip design;

FIG. 3 is a graph illustrating the correlation between the EM fail rate and resistance of IC chips manufactured according to an IC chip design;

FIG. 4 is a flow diagram illustrating an exemplary technique for empirically determining a resistance-to-EM fail rate correlation for an IC chip design at process 104 of FIG. 1;

FIG. 5A is a graph illustrating plotting of test chip-specific resistance values and corresponding test chip-specific EM fail rates;

FIG. 5B is a graph illustrating a resistance-to-EM fail rate curve constructed based on the data points of FIG. 5A;

FIG. 6 is a graph illustrating a maximum resistance threshold defined for an IC chip with respect to a specific product;

FIG. 7 is a chart illustrating a full resistance range for an IC chip design and multiple resistance process windows defined within that full resistance range; and

FIG. 8 is a schematic diagram illustrating an exemplary computer system for implementing aspects of the disclosed method.

### DETAILED DESCRIPTION

As mentioned above, various failure mechanisms can cause the components (e.g., devices, interconnects, etc.) of an integrated circuit (IC) chip to degrade or fail. These failure mechanisms include, but are not limited to, time-dependent dielectric breakdown (TDDB) of the gate dielectric layer or between metal lines, hot carrier injection (HCI), negative bias temperature instability (NBTI), positive bias temperature instability (PBTI), soft error rate (SER), retention disturbance, stress migration (SM) (also referred to as stress-induced voiding (SIV)) and electromigration (EM). Over time these failure mechanisms can impact performance (e.g., operating speed) and/or lead to IC chip failure.

The reliability of an IC chip (also referred to herein as the expected useful life of the IC chip) can be defined in terms of the expected minimum amount of time or, more particularly, the expected minimum number of power-on hours (POHs) during which an IC chip can be expected, with a specified probability, to perform without fail. Reliability is typically determined as a function of multiple different failure mechanisms. Specifically, designers have realized that process parameter variations have a significant impact on IC chip performance (e.g., on operating speed, as indicated by delay). Such process parameter variations are due to variations that occur during manufacturing and include, but are not limited to, variations in channel length, channel width, doping, spacer width, etc. To determine reliability, reliability simulators model the various failure mechanisms in order to determine the fail rates associated with those failure mechanisms across the full process distribution for the design. The full process distribution for the design refers to the performance range of IC chips manufactured according to the design, given a nominal operating voltage. This performance range extends from relatively fast IC chips (e.g., 3σ fast IC chips) at one end of the process distribution (i.e., the “fast” end of the process distribution) to relatively slow IC chips (e.g., 3σ slow IC chips) at the opposite end of the process distribution (i.e., the “slow” end of the process distribution).

In order to ensure that manufactured IC chips will meet reliability specifications despite these failure mechanisms, reliability qualification is performed prior to shipping out manufactured IC chips and/or incorporating them into products. Typically, during reliability qualification, a sample of IC chips manufactured according to a design is selected and subjected to qualification testing to determine whether the sample meets reliability specifications and, particularly, whether the sample has a fail rate that is no greater than an expected overall fail rate for all of the manufactured IC chips. Such qualification testing often involves accelerated stress testing, wherein the sample of IC chips are exercised to simulate field conditions. That is, the IC chips in the sample are each operated at an elevated temperature and/or at an elevated voltage or current for a predefined period of time. The actual fail rate of the sample can then be compared to the expected overall fail rate for all the manufactured IC chips and, if the actual fail rate for the sample is less than or equal to the expected overall fail rate for the manufactured IC chips, the manufactured IC chips can be shipped and/or incorporated into products. However, if the actual fail rate for the sample is higher than the expected overall fail rate for the manufactured IC chips, the manufactured IC chips may have to be scrapped (i.e., not shipped or incorporated into products as planned) and instead design changes and/or process changes may need to be developed. At completion of qualification, the worse case reliability for the entire sample is applied to the entire distribution of parts that will ever be produced in that technology.

Although the above-described technique for performing reliability qualification is quite accurate, it assigns worse case reliability to the entire product distribution for the duration of the technology. Therefore, more efficient techniques are needed for monitoring the manufacturing line and for determining the reliability of particular parts in the product distribution particularly after the technology has been qualified.

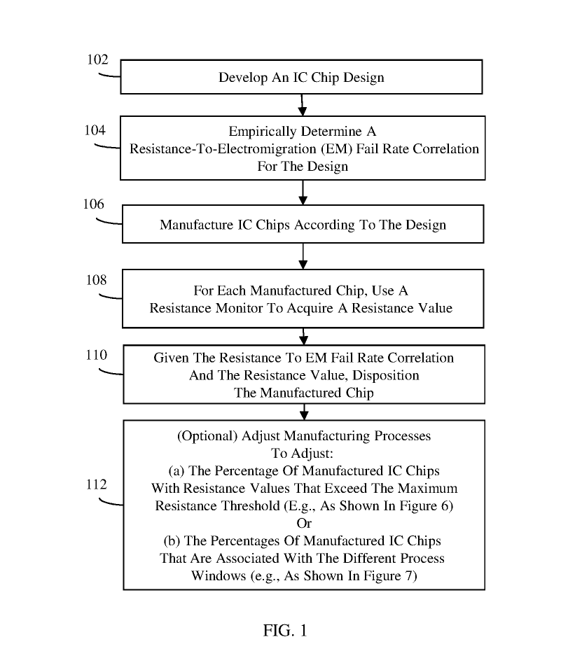

Specifically, referring to the flow diagram of FIG. 1, in the methods disclosed herein an integrated circuit (IC) chip design can be developed (102). This IC chip design can be application-specific (i.e., developed for incorporation into a specific product) or, alternatively, developed for incorporation into multiple different products.

As mentioned above, various failure mechanisms can impact the reliability of an IC chip and these failure mechanisms include, but are not limited to, time-dependent dielectric breakdown (TDDB) of the gate dielectric layer or between metal lines, hot carrier injection (HCI), negative bias temperature instability (NBTI), positive bias temperature instability (PBTI), soft error rate (SER), retention disturbance, stress migration (SM) (also referred to as stress-induced voiding (SIV)) and electromigration (EM). Based on models generated by a reliability simulator, fail rates associated with different failure mechanisms can be determined for a given IC chip design. These various failure mechanism fail rates are then typically used to determine the overall fail rate for the IC chip design using the following expression:

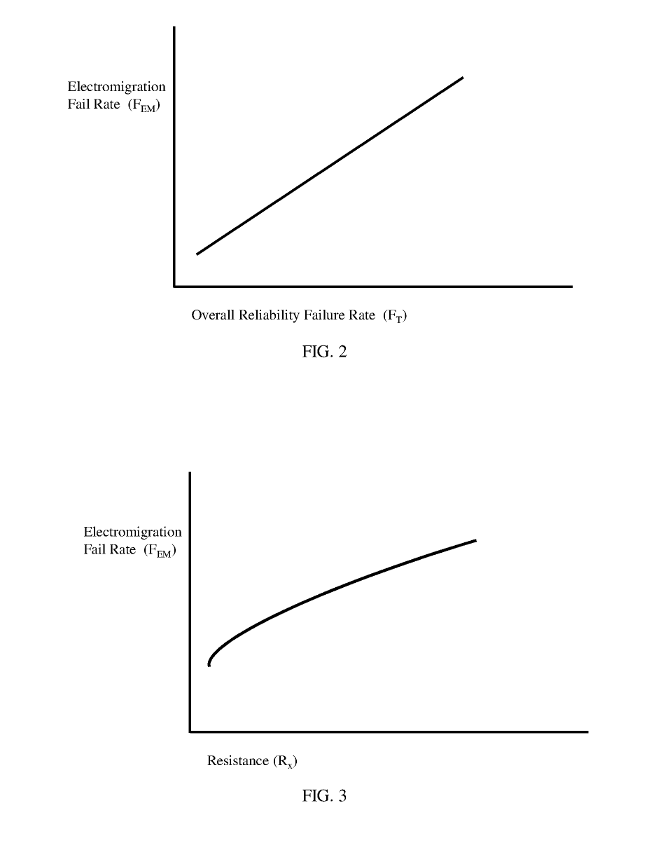

F_{T}=Σᵢ^{N}Fᵢ, (1)

where F_{T} represents the overall fail rate for IC chip design as a function of a selected voltage, temperature and/or frequency, N represents the total number of failure mechanisms, and where Σᵢ^{N}Fᵢ represents the sum of all the different fail mechanism fail rates Fᵢ. However, as IC device sizes continue to be scaled and on-chip device density continues to be increased in new technologies, EM has become a very large, if not, the largest reliability limiter. The methods disclosed herein take advantage of the fact that there is both a direct correlation between the electromigration fail rate (F_{EM}) and the overall fail rate (F_{T}), as illustrated in the graph of FIG. 2, and a correlation between the EM fail rate and resistance, as illustrated in the graph of FIG. 3 and represented by the following expression in order to provide an efficient and accurate technique for performing reliability qualification:

$${F}_{EM} = Φ ( {Z}_{1} + \frac{n}{σ} Log [ \frac{{R}_{x}}{{R}_{1}} ] ) \qquad ( 2 )$$

where Φ is the cumulative distribution function (CDF) or Gaussian distribution, where n is the EM current exponent and σ is the EM failure time distribution shape factor, the values for which are available from technology qualification reports, where Rₓ is the measured resistance for a given structure, where Z₁ is the number of standard deviations (i.e., the number of units sigma), and where R₁ is the nominal resistance for a given technology for a given structure (i.e., the same structure as used for Rₓ). That is, the methods disclosed herein provide for making integrated circuit (IC) chip reliability estimations based on resistance values for a given structure (i.e., a resistance monitor), which can be correlated to an electromigration (EM) fail rate and, thereby the overall fail rate, and for using such estimations to disposition manufactured chips (e.g., to decide whether or not to allow particular manufactured IC chips to be incorporated into specific product(s)).

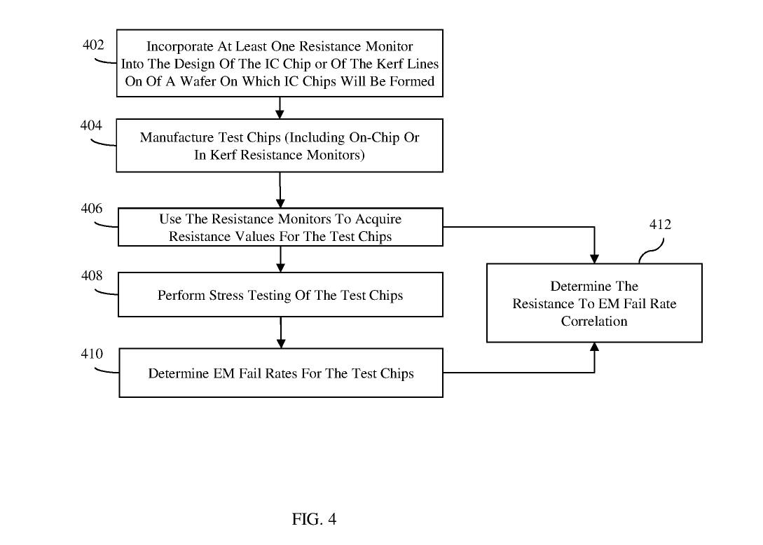

Specifically, in the methods disclosed herein, a resistance-to-electromigration (EM) fail rate correlation can be empirically determined for an IC chip design (104). As illustrated in the flow diagram of FIG. 4, this correlation can be empirically determined by incorporating at least one resistance monitor into the design of the IC chip and/or into the design of the Kerf lines on a semiconductor wafer on which such IC chips will be fabricated (402). Various different on-chip and in-Kerf resistance monitor structures are known in the art and, thus, the details of such structure are omitted from this specification in order to allow the reader to focus on the salient aspects of the disclosed methods. In any case, those skilled in the art will recognize that such a resistance monitor often includes a metal element (e.g., a metal line or serpentine, with or without via) and an on- or off-chip detection circuit that compares a voltage drop across the monitored element with a voltage drop across a reference element. In the design, a resistance monitor can be located in particular metal level or resistance monitors can be located each of the metal levels without consideration of critical EM concerns. Alternatively, resistance monitor(s) can be located at or adjacent EM critical area(s) (i.e., at or adjacent area(s) where EM is of particular concern and, more particularly, at or adjacent area(s) where EM is at a higher risk of occurring, for example, due to wire density and/or where EM fail could be catastrophic to the application).

Multiple test chips can then be manufactured so as to include the on-chip and/or in-Kerf resistance monitors, as designed, and the resistance monitors can be used to acquire resistance values for each of the test chips (404)-(406). It should be understood that, if the resistance monitors are in-Kerf resistance monitors, at least one specific in-Kerf resistance monitor can be adjacent to and associated with each test chip on the semiconductor wafer and testing to acquire resistance values for the test chips can be performed at the wafer level. However, if the resistance monitors are on-chip resistance monitors, testing to acquire resistance values for the test chips can be performed either at the wafer level or at the chip level. If a single resistance monitor is associated with a single test chip, then the resistance value at process 412, described below, to determine the resistance-to-EM fail rate correlation can be a single resistance measurement acquired from that single resistance monitor. However, if multiple resistance monitors (on-chip and/or in-Kerf resistance monitors) are associated with a single test chip, the resistance value used at process 412, described below, to determine the resistance-to-EM fail rate correlation should be the worst-case resistance value (i.e., the highest resistance value) acquired from the multiple resistance monitors.

After the resistance values for the test chips are acquired, stress testing of the test chips can be performed and, based on the results of the stress testing, corresponding test chip-specific EM fail rates for the test chips can be determined (408)-(410). That is, the test chips can be forced to undergo accelerated stress testing, wherein they are exercised to simulate field conditions. That is, the test chips can each be operated at an elevated temperature and/or at an elevated voltage or current for a predefined period of time. Next, each test chip can be evaluated to determine the cumulative number of EM fails on that test chip and the median time to failure (MTTF) for the EM failures or the time for 50% failure (t₅₀) for that particular test chip can be calculated.

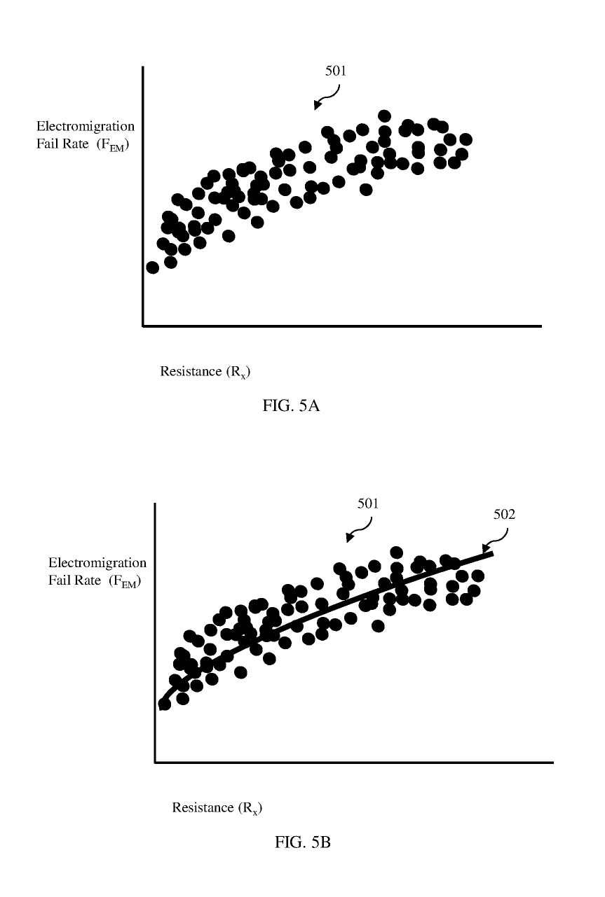

Next, the resistance values acquired for the test chips at process 406 and the EM fail distribution calculated for the test chips at process 410 can be used to determine a resistance-to-EM fail rate correlation (412). Specifically, the test chip-specific resistance values and the corresponding test chip-specific EM fail rates can be plotted as data points 501 on a graph, as shown in FIG. 5A. That is, for each test chips, its resistance value and its EM fail rate can be plotted as a single data point on a graph. Then, using on all of the data points 501 for all of the test chips, a curve fitting process can be performed in order to construct the resistance-to-EM fail rate curve 502, as shown in the graph of FIG. 5B. Once the resistance-to-EM fail rate curve 502 is established, it can be used to develop a function that defines the resistance-to-EM fail rate correlation.

Referring again to FIG. 1, subsequently multiple IC chips can be manufactured according to the design and including the same on-chip and/or Kerf line resistance monitors as used for the test chips (106).

For each manufactured IC chip, the following processes can be performed. At least one resistance monitor can be used to acquire a resistance value for the manufactured IC chip (108). It should be understood that, as with the test chips, the resistance monitors for the manufactured IC chips can be on-chip resistance monitors and/or in-Kerf line resistance monitors. If the resistance monitors are in-Kerf resistance monitors, at least one specific in-Kerf resistance monitor can be adjacent to and associated with each test chip on the semiconductor wafer and testing to acquire resistance values for the test chips can be performed at the wafer level. However, if the resistance monitors are on-chip resistance monitors, testing to acquire resistance values for the test chips can be performed either at the wafer level or at the chip level. Finally, if multiple resistance monitors (on-chip and/or in-Kerf resistance monitors) are associated with a single manufactured chip, the resistance value acquired at process 108 should be the worst case resistance value (i.e., the highest resistance value) acquired. Then, given the resistance value for the manufactured IC chip and the resistance-to-EM fail rate correlation, the manufactured IC chip can be dispositioned in different ways depending upon whether one specific product or multiple different product can incorporate IC chip(s) manufactured according to the same IC chip design (110).

More particularly, one method disclosed herein can apply to a situation where IC chips manufactured according to an IC chip design are to be incorporated into one specific product. In this method, a product-level reliability requirement for the specific product can be determined. For example, the required minimum number of power-on hours (POHs) during which the product can be expected, with a specified probability, to perform without fail can be determined. Then, a chip-level reliability requirement, which is necessary to achieve the product-level reliability requirement, can be determined. That is, the required minimum number of power-on hours (POHs) during which the IC chip should, with a specified probability, perform without fail in order to ensure that the product-level reliability requirement is met can be determined.

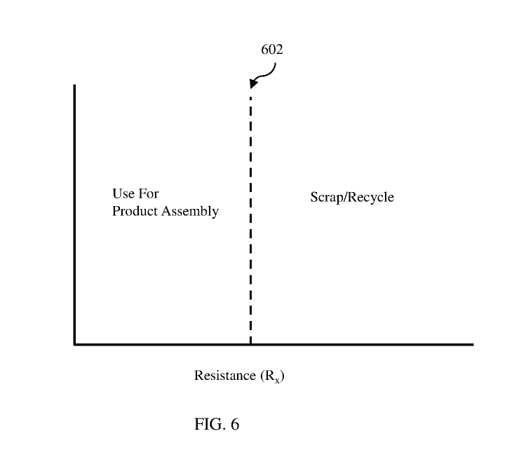

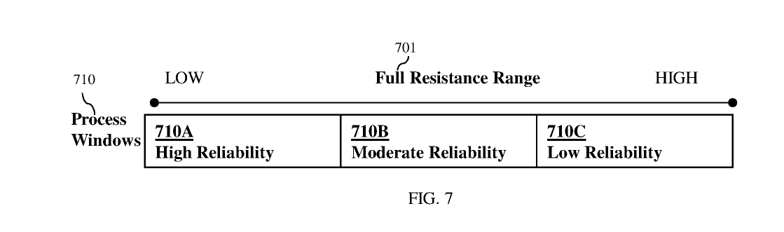

Next, the maximum resistance threshold for the IC chip with respect to the specific product can be defined. Specifically, given the chip-level reliability requirement, which as discussed above and illustrated in FIG. 2 is directly correlated to the EM fail rate, and given the resistance-to-EM fail rate correlation, the maximum resistance threshold 602 for the IC chip with respect to the specific product can be defined, as shown in FIG. 6. That is, the highest resistance value that a manufactured IC can have and still meet the chip-level reliability requirement and, thereby the product-level reliability requirement can be determined.

Subsequently, during dispositioning of manufactured IC chips, for each manufactured IC chip the resistance value acquired for that IC chip at process 108 can be compared to the maximum resistance threshold 602. If the manufactured IC chip has a resistance value that is below the maximum resistance threshold 602, it can be allowed to be incorporated into the specific product (e.g., it can be shipped out for use in product assembly). However, if the manufactured IC chip has a resistance value that is at or above the maximum resistance threshold 602, the manufactured IC chip can not be used in the specific product and is, thus, scrapped or recycled.

In addition to the processes described above, this method can further include selectively adjusting the manufacturing processes used during the manufacturing of the IC chips in order to selectively adjust the percentage of manufactured IC chips that exceed the chip-level reliability requirement (112). That is, if the manufacturing processes do not result in a high enough yield of manufactured IC chips with resistance values below the maximum resistance threshold, changes can be made in the manufacturing process to improve yield by adjusting resistance such that more parts are produced with the desired resistance/EM/reliability.

Another method disclosed herein can apply to situations where IC chips manufactured according to the same IC chip design could be incorporated into various different products having various different product-level reliability requirements and, thereby different chip-level reliability requirements. In this case, the full resistance range 701 for the integrated circuit chip design can be determined and, after the full resistance range 701 is determined, multiple resistance process windows 710 within that full resistance range can be defined, as shown in FIG. 7. Specifically, the full range 701 of possible resistance values from a lowest resistance value to a highest resistance value for IC chips manufactured according to the IC design can be defined. This can be accomplished through simulations or, alternatively, based on the actual resistance values acquired from the resistance monitors associated with the test chips at process 108. This full resistance range 701 can then be divided into resistance process windows that correspond to different resistance ranges within the full resistance range. For illustration purposes, three resistance process windows 710A-710C are shown; however, it should be understood that the full resistance range can be divided into any number of two or more resistance process windows.

Expected reliability ranges can then be associated with the different resistance process windows, respectively. That is, since there is a known correlation between resistance and the EM fail rate for the IC chip design, as discussed above and determined at process 108, and since the EM fail rate is directly related to the overall fail rate, as discussed above and illustrated in FIG. 2, different expected reliability ranges can be associated with the different resistance process windows. For example, since the first resistance process window 710A is associated with a relatively low range of resistance values and, thereby a relatively low EM fail rate range, the first resistance process window 710A will also be associated with a relatively high expected reliability range. Since the second resistance process window 710B is associated with a mid-range of resistance values, the second resistance process window 710B will be associated with a moderate expected reliability range. Since the third resistance process window 710C is associated with a relatively high range of resistance values and, thereby a relatively high EM fail rate range, the third resistance process window 710C will also be associated with a relatively low expected reliability range.

Additionally, for the different products each designed to incorporate at least one of the manufactured IC chips, product-level reliability requirements and chip-level reliability requirements necessary to achieve the product-level reliability requirements, respectively, can be determined. For example, for each of the different products at issue, the required minimum number of power-on hours (POHs) during which the product can be expected, with a specified probability, to perform without fail can be determined. Then, for each of the different products at issue, a chip-level reliability requirement, which is necessary to achieve the product-level reliability requirement, can be determined. That is, the required minimum number of power-on hours (POHs) during which the IC chip should, with a specified probability, perform without fail in order to ensure that the product-level reliability requirement is met can be determined. Based on the chip-level reliability requirements, each of the products can then be associated with at least one of the resistance process windows. For example, a first product that requires the IC chip have a relatively high reliability can be associated with the first resistance process window 710A, a second product that requires the IC chip have a moderate reliability can be associated with the second resistance process window 710B, and a third product that requires that the IC chip have only a low reliability can be associated with the third resistance process window 710C.

Subsequently, during dispositioning of the manufactured IC chips, each manufactured IC chip can be associated with a specific resistance process window based on the resistance value acquired for that manufactured IC chip at process 108. Specifically, a manufactured IC chip having a resistance value falling within the resistance value range for the first resistance process window 710A will be associated with that first resistance process window 710A; a manufactured IC chip having a resistance value falling within the resistance value range for the second resistance process window 710B will be associated with the second resistance process window 710B, and so on. Selection of manufactured IC chips for incorporation into the different products can then be made based on the resistance process windows. That is, a manufactured IC chip may only be selectable for incorporation into a specific product when it and the specific product have been associated with the same specific resistance process window. Alternatively, a manufactured IC chip may be selectable for incorporation into a specific product when it and the specific product have been associated with the same specific resistance process window or, optionally, when the manufactured IC chip is associated with a different resistance process window having a higher expected reliability range.

In addition to the processes described above, this method can further include selectively adjusting the manufacturing processes used during the manufacturing of the IC chips in order to selectively adjust the percentages of the manufactured IC chips associated with each of the different resistance process windows (112). For example, if more higher reliability IC chips are required, the manufacturing processes can be adjusted to increase the number of IC chips falling in the first resistance process window 710A. Alternatively, if fewer higher reliability IC chips are required, the manufacturing processes can be adjusted to reduce the number of higher reliability IC chips and potentially the costs associated with production.

Aspects of the disclosed methods (e.g., processes used when defining the full resistance range, dividing the full resistance range into resistance process windows, determining the resistance-to-EM fail rate correlation based on acquired data points, etc.) can be implemented using a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may incorporate copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-determining data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein is an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which includes one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

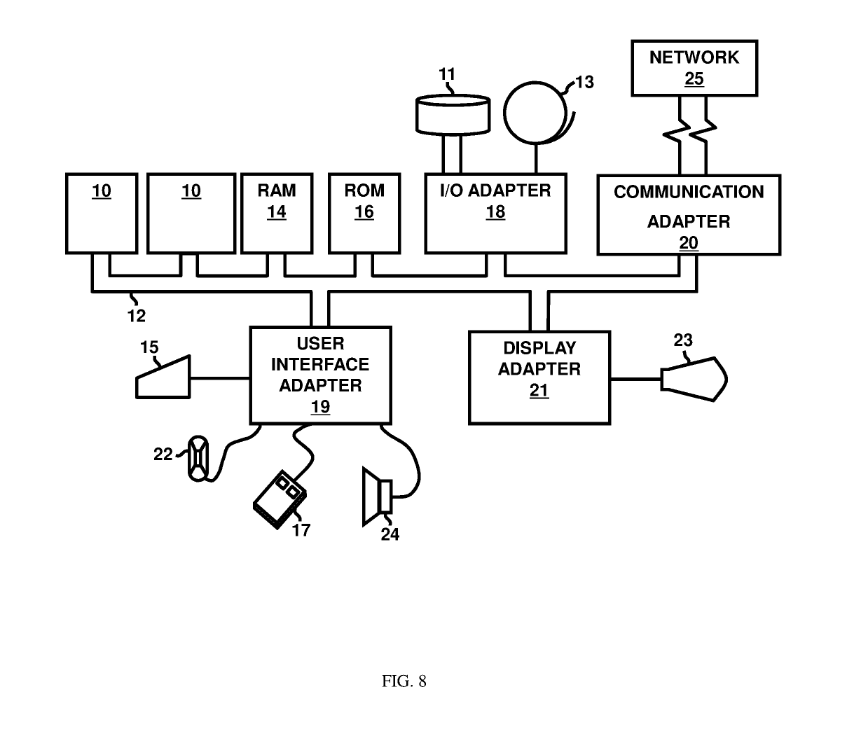

A representative hardware environment (i.e., a computer system) for implementing aspects of the methods, as described above, is depicted in FIG. 8. This schematic drawing illustrates a hardware configuration of an information handling/computer system in accordance with the embodiments herein. The system incorporates at least one processor or central processing unit (CPU) 10. The CPUs 10 are interconnected via a system bus 12 to various devices such as a random access memory (RAM) 14, read-only memory (ROM) 16, and an input/output (I/O) adapter 18. The I/O adapter 18 can connect to peripheral devices, such as disk units 11 and tape drives 13, or other program storage devices that are readable by the system. The system can read the inventive instructions on the program storage devices and follow these instructions to execute the methodology of the embodiments herein. The system further includes a user interface adapter 19 that connects a keyboard 15, mouse 17, speaker 24, microphone 22, and/or other user interface devices such as a touch screen device (not shown) to the bus 12 to gather user input. Additionally, a communication adapter 20 connects the bus 12 to a data processing network 25, and a display adapter 21 connects the bus 12 to a display device 23 which may be embodied as an output device such as a monitor, printer, or transmitter, for example.

It should be understood that the terminology used herein is for the purpose of describing the disclosed methods and is not intended to be limiting. For example, as used herein, the singular forms “a”, “an” and “the” are intended to include the plural forms as well, unless the context clearly indicates otherwise. Additionally, as used herein, the terms “comprises” “comprising”, “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “on”, “in direct contact”, “abutting”, “directly adjacent to”, etc., are intended to indicate that at least one element physically contacts another element (without other elements separating the described elements). The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Therefore, disclosed above are methods for making integrated circuit (IC) chip reliability estimations based on resistance values, which can be correlated to the electromigration (EM) fail rate and, thereby the overall fail rate, and for using such estimations to disposition manufactured IC chips (e.g., to decide whether or not to allow particular manufactured IC chips to be incorporated into specific product(s)). In the methods, a resistance-to-EM fail rate correlation can be empirically determined for an integrated circuit chip design. Additionally, for each IC chip manufactured according to the design, at least one resistance monitor can be used to acquire a resistance value for that manufactured IC chip. Then, given the resistance value and the resistance-to-EM fail rate correlation, the manufactured IC chip can be dispositioned in different ways depending upon whether one specific product or multiple different product can incorporate IC chip(s) manufactured according to the IC chip design.

What is claimed is:

1. A method comprising:
empirically determining a resistance-to-electromigration fail rate correlation for an integrated circuit chip design;
using at least one resistance monitor to acquire a resistance value for a manufactured chip, the manufactured chip having been manufactured according to the design; and,
given the resistance-to-electromigration fail rate correlation and the resistance value, dispositioning the manufactured chip.

2. The method of claim 1, the empirically determining comprising:
providing multiple test chips manufactured according to the design;
using resistance monitors to acquire test chip-specific resistance values for the test chips;
performing stress testing of the test chips to determine corresponding test chip-specific electromigration fail rates for the test chips;
plotting the test chip-specific resistance values and the corresponding test chip-specific electromigration fail rates as data points on a graph;
constructing a resistance-to-electromigration fail rate curve, based on the data points; and
defining the resistance-to-electromigration fail rate correlation, based on the resistance-to-electromigration fail rate curve.

3. The method of claim 1, the resistance value for the manufactured chip being a single resistance measurement from a single resistance monitor or being based on multiple resistance measurements from multiple resistance monitors.

4. The method of claim 1, the resistance value for the manufactured chip being associated with at least one electromigration critical area.

5. The method of claim 1, the resistance monitor being located on the manufactured chip.

6. The method of claim 1, the manufactured chip being one of multiple manufactured chips on a semiconductor wafer and the at least one resistance monitor being located in a kerf line between the manufactured chips.

7. The method of claim 1, the dispositioning of the manufactured chip comprising:
based on the resistance value and the resistance-to-electromigration fail rate correlation, estimating an expected reliability of the manufactured chip; and,
selecting the manufactured chip for incorporation into a product only when the expected reliability meets a chip-level reliability requirement for the product.

8. The method of claim 1, the dispositioning of the manufactured chip comprising:
based on the resistance value, associating the manufactured chip with one resistance process window out of multiple resistance process windows, wherein the resistance process windows correspond to different resistance ranges within a full resistance range and, thereby to different expected reliability ranges given the resistance-to-electromigration fail rate correlation; and,
selecting the manufactured chip for incorporation into a product only when a chip-level reliability requirement for the product falls within an expected reliability range associated with the resistance process window.

9. A method comprising:
empirically determining a resistance-to-electromigration fail rate correlation for an integrated circuit chip design;
manufacturing chips according to the design;
determining a product-level reliability requirement for a product designed to incorporate at least one of the manufactured chips and a chip-level reliability requirement necessary to achieve the product-level reliability requirement;
given the resistance-to-electromigration fail rate correlation, determining a maximum resistance threshold for ensuring the chip-level reliability requirement is met; and,
for each manufactured chip, performing the following:
using at least one resistance monitor to acquire a resistance value for the manufactured chip; and,
dispositioning the manufactured chip, the dispositioning comprising:
comparing the resistance value to the maximum resistance threshold; and
allowing the manufactured chip to be incorporated into the product only when the resistance value is below the maximum resistance threshold.

10. The method of claim 9, the empirically determining comprising:
providing multiple test chips manufactured according to the design;
using resistance monitors to acquire test chip-specific resistance values for the test chips;
performing stress testing of the test chips to determine corresponding test chip-specific electromigration fail rates for the test chips;
plotting the test chip-specific resistance values and the corresponding test chip-specific electromigration fail rates as data points on a graph;
constructing a resistance-to-electromigration fail rate curve, based on the data points; and
defining the resistance-to-electromigration fail rate correlation, based on the resistance-to-electromigration fail rate curve.

11. The method of claim 9, the resistance value for the manufactured chip being a single resistance measurement from a single resistance monitor or being based on multiple resistance measurements from multiple resistance monitors.

12. The method of claim 9, the resistance value for the manufactured chip being associated with at least one electromigration critical area.

13. The method of claim 9, the resistance monitor being located on the manufactured chip.

14. The method of claim 9, the manufactured chip being one of multiple manufactured chips on a semiconductor wafer and the at least one resistance monitor being located in a kerf line between the manufactured chips.

15. The method of claim 9, further comprising: selectively adjusting manufacturing processes used during the manufacturing of the chips in order to selectively adjust a percentage of the manufactured chips that exceed the chip-level reliability requirement.

16. A method comprising:
defining multiple resistance process windows within a full resistance range for an integrated circuit chip design, the resistance process windows corresponding to different resistance ranges;
empirically determining a resistance-to-electromigration fail rate correlation for the design;
based on the resistance-to-electromigration fail rate correlation, associating expected reliability ranges with the resistance process windows, respectively;
manufacturing chips according to the design;
for each product of multiple different products designed to incorporate at least one of the manufactured chips, performing the following:
determining a product-level reliability requirement and a chip-level reliability requirements necessary to achieve the product-level reliability requirement; and,
based on the chip-level reliability requirement, associating the product with at least one of the resistance process windows; and,
for each manufactured chip, performing the following:
using at least one resistance monitor to acquire a resistance value for the manufactured chip; and,
dispositioning the manufactured chip, the dispositioning comprising associating the manufactured chip with a specific resistance process window, based on the resistance value, the manufactured chip being subsequently selectable for incorporation into the product when the product is associated with the specific resistance process window.

17. The method of claim 16, the empirically determining comprising:
providing multiple test chips manufactured according to the design;
using resistance monitors to acquire test chip-specific resistance values for the test chips;
performing stress testing of the test chips to determine corresponding test chip-specific electromigration fail rates for the test chips;
plotting the test chip-specific resistance values and the corresponding test chip-specific electromigration fail rates as data points on a graph;
constructing a resistance-to-electromigration fail rate curve, based on the data points; and
defining the resistance-to-electromigration fail rate correlation, based on the resistance-to-electromigration fail rate curve.

18. The method of claim 16, the resistance value for the manufactured chip being a single resistance measurement from a single resistance monitor or being based on multiple resistance measurements from multiple resistance monitors.

19. The method of claim 16, the resistance value for the manufactured chip being associated with at least one electromigration critical area.

20. The method of claim 16, further comprising: selectively adjusting the manufacturing processes used during the manufacturing of the chips in order to selectively adjust percentages of the manufactured chips associated with the resistance process windows.
